(19) United States
(12) Patent Application Publication
(10) Pub. No.: US 2026/0371886 A1
(43) Pub. Date: Nov. 19, 2026

(54) DISPLAY PANEL, METHOD FOR MANUFACTURING THE SAME, AND TOUCH DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Kailong ZUO, Beijing (CN); Li HUANG, Beijing (CN); Zhengdong ZHANG, Beijing (CN)

(21) Appl. No.: 19/148,345

(22) PCT Filed: Jun. 5, 2024
(86) PCT No.: PCT/CN2024/097461

§ 371 Date: Jul. 16, 2025

(30) Foreign Application Priority Data
Jun. 7, 2023 (CN) 202310673654.X

(51) Int. Cl. H10K 59/38; G06F 3/041; G06F 3/044; H10K 59/12; H10K 59/40

(52) U.S. Cl. CPC H10K 59/38; G06F 3/0412; G06F 3/0446; H10K 59/1201; H10K 59/40; G06F 2203/04107

(57) ABSTRACT

The present disclosure provides a display panel, a method for manufacturing the same, and a touch display device. The display panel includes: a display substrate (10), a color filter layer (13), and a plurality of tactile sensor units (20). The display substrate (10) includes a base substrate and a plurality of pixel units. The color filter layer (13) includes a plurality of color filter units (131), and every adjacent ones of the plurality of color filter units (131) have therebetween opening regions (132), respectively. The plurality of tactile sensor units (20) are disposed in the respective opening regions (132) between the color filter units (131). Further, each of the plurality of tactile sensor units (20) includes a black light shielding material, and an orthogonal projection of the black light shielding material on the base substrate covers a respective opening region (132) between the color filter units (131).

### CROSS-REFERENCE TO RELATED APPLICATIONS

This is a National Phase Application filed under 35 U.S.C. 371 as a national stage of PCT/CN2024/097461 filed on Jun. 5, 2024, which claims priority to Chinese patent application No. 202310673654.X, filed on Jun. 7, 2023, the entire content of each of which is incorporated herein by reference.

### TECHNICAL FIELD

The present disclosure relates to the field of display technology, and in particular, to a display panel, a method for manufacturing the display panel, and a touch display device.

### BACKGROUND

In recent years, as the Color Filter On Encapsulation (COE) technology for a flexible Organic Light Emitting diode (OLED) becomes mature, the adoption of the COE technology instead of a polarizer (POL) has become a trend of iteration of subsequent display screens. The COE technology can improve a transmittance of outgoing light of a display device, thereby reducing a power consumption of a display screen, and improving a battery life of a mobile terminal product. However, for a display device adopting an in-screen touch structure, a COE structure may cause some problems, such as a greater viewing angle brightness attenuation (which may be referred to as L_decay), than a POL structure.

### SUMMARY

Some embodiments of the present disclosure provide a display panel, a method for manufacturing the display panel, and a touch display device, to at least solve the problem that a viewing angle brightness of a COE screen is attenuated too quickly.

In a first aspect, some embodiments of the present disclosure further provide a display panel, which includes: a display substrate including a base substrate and a plurality of pixel units arranged on the base substrate, wherein each of the plurality of pixel units includes a plurality of sub-pixels; a color filter layer arranged on the display substrate and including a plurality of color filter units, wherein every adjacent ones of the plurality of color filter units have therebetween opening regions, respectively; and a plurality of tactile sensor units disposed in the opening regions, respectively, wherein each of the plurality of tactile sensor units includes a black light shielding material, and an orthogonal projection of the black light shielding material on the base substrate covers a respective opening region.

In some embodiments, each of the tactile sensor units includes a first electrode layer, a second electrode layer, and an electrolyte layer positioned between the first electrode layer and the second electrode layer, and at least one of the first electrode layer, the second electrode layer, or the electrolyte layer includes the black light shielding material; and an interface between the first electrode layer and the electrolyte layer is a first interface, an interface between the second electrode layer and the electrolyte layer is a second interface, the first electrode layer is configured to receive a first voltage signal, the second electrode layer is configured to receive a second voltage signal, the first voltage signal and the second voltage signal have therebetween a voltage difference such that interface capacitances are respectively formed at the first interface and the second interface, and the interface capacitances at the first interface and/or the second interface are changed in response to a touch operation performed by a user and are recovered after the touch operation is finished.

In some embodiments, at least one of the first electrode layer, the second electrode layer, or the electrolyte layer has therein gaps, and in response to the touch operation performed by the user, the gaps at a corresponding position are compressed, such that an effective contact area at the first interface and/or the second interface is increased, and the interface capacitances are increased.

In some embodiments, each of the first electrode layer and the second electrode layer includes a composite layer of polymer fiber and conductive nano material, and the conductive nano material is a black conductive nano material; and the electrolyte layer includes a composite fiber of elastic polymer material and electrolyte material.

In some embodiments, a material of the polymer fiber includes one or more of thermoplastic polyurethane, polypropylene, polyvinylidene fluoride, polyethylene, or nylon; the conductive nano material is carbon fiber, a carbon nanotube, or graphene; the elastic polymer material includes one or more of thermoplastic polyurethane, polyethylene, or nylon; and the electrolyte material includes one or more of 1-hexyl-3-methylimidazolium tetrafluoroborate, 1-butyl-3-methylimidazolium tetrafluoroborate, or tert-butyl peroxyacetate.

In some embodiments, the first electrode layers of any adjacent two of the plurality of tactile sensor units are spaced apart from each other, and the second electrode layers of the plurality of tactile sensor units are connected to each other.

In some embodiments, the display panel further includes a grounding signal line and touch signal lines corresponding to the respective tactile sensor units, wherein the first electrode layer of each tactile sensor unit is connected to a respective touch signal line, the touch signal lines are configured to transmit touch signals of the respective tactile sensor units, and the second electrode layers of the tactile sensor units are connected to the grounding signal line.

In some embodiments, each first electrode layer is closer to the display substrate than a respective second electrode layer, the display panel further includes a conductive pattern layer arranged on a side of each first electrode layer proximal to the display substrate, and the touch signal lines are arranged in the conductive pattern layer.

In some embodiments, a material of the conductive pattern layer is a transparent conductive material.

In some embodiments, each first electrode layer is closer to the display substrate than each second electrode layer, the display substrate includes a light emitting device layer disposed on the base substrate, the light emitting device layer includes a plurality of light emitting devices for forming the plurality of pixel units; and a metal wiring layer is arranged between the base substrate and the light emitting device layer, the touch signal lines are arranged in the metal wiring layer, and the first electrode layer of each tactile sensor unit is connected to a respective touch signal line through a via.

In some embodiments, the light emitting device layer includes a pixel defining layer having pixel openings within which the plurality of light emitting devices are respectively disposed; and in a direction perpendicular to the base substrate, vias that are in communication with each other in sequence are formed in an insulating layer between each first electrode layer and the pixel defining layer, the pixel defining layer, and an insulating layer between the pixel defining layer and the metal wiring layer, a connection member is arranged in the vias, and the first electrode layer of each tactile sensor unit is connected to a respective touch signal line in the metal wiring layer through the connection member.

In some embodiments, the display panel further includes a first inorganic encapsulation layer, an organic encapsulation layer, and a second inorganic encapsulation layer; wherein the display substrate includes a light emitting device layer arranged on the base substrate, the first inorganic encapsulation layer is arranged on a side of the light emitting device layer proximal to the color filter layer and the tactile sensor units, and the organic encapsulation layer and the second inorganic encapsulation layer are sequentially stacked on a side of the color filter layer and the tactile sensor units distal to the light emitting device layer.

In a second aspect, some embodiments of the present disclosure further provide a method for manufacturing a display panel, the method including: preparing a display substrate, wherein the display substrate includes a base substrate and a plurality of pixel units arranged on the base substrate, and each of plurality of pixel units includes a plurality of sub-pixels; forming a color filter layer on the display substrate, wherein the color filter layer includes a plurality of color filter units, and every adjacent ones of the plurality of color filter units have therebetween opening regions, respectively; and forming a plurality of tactile sensor units in the opening regions in the color filter layer, respectively, wherein each of the plurality of tactile sensor units includes a black light shielding material, and an orthogonal projection of the black light shielding material on the base substrate covers a respective opening region.

In some embodiments, the forming a plurality of tactile sensor units in the opening regions in the color filter layer includes: forming first electrode layers of the tactile sensor units in the respective opening regions, wherein the first electrode layers of any adjacent two of the tactile sensor units are spaced apart from each other; forming an electrolyte layer on the first electrode layer in a respective opening region; and forming a second electrode layer on the electrolyte layer in the respective opening region.

In a third aspect, some embodiments of the present disclosure further provide a display device, which includes the display panel according to any one of the embodiments of the first aspect.

The foregoing is merely a summary of the technical solutions provided by some embodiments of the present disclosure. To enable a clear understanding of the technical solutions, which may be implemented in light of the following description, provided by some embodiments of the present disclosure, and to enable the above and other objects, features, and advantages of some embodiments of the present disclosure to be more clearly understood, detailed implementations of some embodiments of the present disclosure will be provided and described below.

### BRIEF DESCRIPTION OF THE DRAWINGS

Various additional advantages and benefits will become apparent to one of ordinary skill in the art upon reading the following detailed description of the exemplary embodiments. The drawings are only for purposes of illustrating the exemplary embodiments and are not to be construed as limiting the present disclosure. Further, like reference symbols are adopted to refer to like parts throughout the drawings, in which:

FIG. 1 is a schematic diagram illustrating a structure of a display panel according to some embodiments of the present disclosure;

FIG. 2 is a schematic diagram illustrating an arrangement of tactile sensor units according to some embodiments of the present disclosure;

FIG. 3 is a schematic diagram illustrating a configuration of a tactile sensor unit according to some embodiments of the present disclosure;

FIG. 4 is a schematic diagram illustrating a structure of a display panel according to a comparative embodiment;

FIG. 5 is a schematic diagram illustrating a state of a tactile sensor unit at a first stage according to some embodiments of the present disclosure;

FIG. 6 a schematic diagram illustrating a state of a tactile sensor unit at a second stage according to some embodiments of the present disclosure;

FIG. 7 is a schematic diagram illustrating an equivalent circuit of a tactile sensor unit according to some embodiments of the present disclosure;

FIG. 8 is a schematic diagram illustrating an arrangement of first electrode layers of tactile sensor units according to some embodiments of the present disclosure;

FIG. 9 is a schematic diagram illustrating a structure of a display panel according to still other embodiments of the present disclosure;

FIG. 10 is a flowchart illustrating a method for manufacturing a display panel according to some embodiments of the present disclosure;

FIGS. 11A to 11H are schematic diagrams illustrating a first exemplary process for a display panel according to some embodiments of the present disclosure; and

FIGS. 12A to 12H are schematic diagrams illustrating a second exemplary process for a display panel according to some embodiments of the present disclosure.

### DETAILED DESCRIPTION OF EMBODIMENTS

Exemplary embodiments of the present disclosure will be described in more detail below with reference to the accompanying drawings. While exemplary embodiments of the present disclosure are shown in the drawings, it should be understood that the present disclosure may be embodied in various forms and should not be limited to the embodiments set forth herein. Rather, these embodiments are provided such that the present disclosure will be thorough and complete, and will fully convey the scope of the present disclosure to one of ordinary skill in the art.

It should be noted that the expression “and/or” adopted herein is only one kind of association relationship describing the associated objects, and means that three relationships may exist, for example, the expression “A and/or B” may mean: A exists alone, both A and B exist, and B exists alone. The term “a plurality of”′ used herein includes cases of two or more.

As used herein, the term “about,” “roughly” or “approximately” includes the stated value as well as average values within an acceptable range of deviation for the particular value as determined by one of ordinary skill in the art in view of the measurement in question and the error associated with measuring a particular quantity (i.e., the limitations of a measurement system).

As used herein, the term “being parallel to”, “being perpendicular to”, or “being equal to” includes the stated case and cases that approximate the stated case to within an acceptable range of deviation as determined by one of ordinary skill in the art in view of the measurement in question and the error associated with the measurement of a particular quantity (i.e., the limitations of a measurement system). For example, “being parallel to” includes absolute parallelism and approximate parallelism, where an acceptable deviation from approximate parallelism may be, for example, within 5°. Further, “being perpendicular to” includes absolute perpendicularity and approximate perpendicularity, where an acceptable deviation from approximate perpendicularity may also be, for example, within 5°. In addition, “being equal to” includes absolute equality and approximate equality, where an acceptable deviation from approximate equality may be, for example, a difference between two equal quantities is less than or equal to 5% of either to the two equal quantities.

It will be understood that when a layer or an element is referred to as being “on” another layer or substrate, it can be directly on the other layer or substrate, or intervening layers may also be present between the layer or element and the other layer or substrate.

In a first aspect, some embodiments of the present disclosure provide a display panel. Referring to FIGS. 1 to 3, the display panel includes a display substrate 10, and a color filter layer 13 and a plurality of tactile sensor units 20, which are arranged on the display substrate 10. The display substrate 10 includes a base substrate and a plurality of pixel units arranged on the base substrate, and each of the plurality of pixel units includes a plurality of sub-pixels.

For example, the base substrate may be a rigid substrate. The rigid substrate may include, for example, a glass substrate, a polymethyl methacrylate (PMMA) substrate, a silicon substrate, or the like. In this case, the display panel may be a rigid display panel.

For another example, the base substrate may be a rigid substrate, or a flexible substrate. The flexible substrate may include, for example, a polyethylene terephthalate (PET) substrate, a polyethylene naphthalate two formic acid glycol ester (PEN) substrate, a polyimide (PI) substrate, or the like. In this case, the display panel may be a flexible display panel.

In should be noted that, the base substrate may have a single-layer structure or a multi-layer structure. For example, the base substrate may include at least one flexible substrate and at least one buffer layer, and the at least one flexible substrate and the at least one buffer layer are alternately stacked together.

For example, the plurality of pixel units are distributed in an array in a first direction and a second direction. That is, the plurality of pixel units are arranged in M rows and N columns, where each of M and N is an integer greater than or equal to 2. The first direction may be a pixel row direction, and the second direction may be a pixel column direction. The first direction and the second direction intersect, such as are perpendicular to, each other.

Each pixel unit includes a plurality of sub-pixels. Each sub-pixel can display a single color, for example, a red sub-pixel displays red, a green sub-pixel displays green, and a blue sub-pixel displays blue. Brightness (i.e., gray scales) of the sub-pixels of different colors in each pixel may be adjusted, and the display of multiple colors may be realized through color combination and superposition, such that the full-color display of the display panel is realized.

Each sub-pixel may include a light emitting device 101 and a pixel driving circuit for driving the light emitting device 101. For example, the light emitting device 101 may be an organic light emitting diode (OLED), a micro organic light emitting diode (Micro OLED), a quantum dot organic light emitting diode (QLED), or the like. For example, each red sub-pixel may include the light emitting device 101 for emitting red light, each green sub-pixel may include the light emitting device 101 for emitting green light, and each blue sub-pixel may include the light emitting device 101 for emitting blue light.

The pixel driving circuit may include electronic elements such as a plurality of transistors and a capacitor. For example, the pixel driving circuit may include three transistors and one capacitor, which may be referred to as 3T1C (i.e., one driving transistor, two switch transistors, and one capacitor). Alternatively, the pixel driving circuit may include more than three transistors and at least one capacitor, such as 4T1C (i.e., one driving transistor, three switch transistors, and one capacitor), 5T1C (i.e., one driving transistor, four switch transistors, and one capacitor), 7T1C (i.e., one driving transistor, six switch transistors, and one capacitor), or the like. Each transistor may be a film transistor (TFT), a field effect transistor (which may be of metal oxide semiconductor, MOS), or another switch device with the same characteristics.

It will be appreciated that each transistor may include a control electrode, a first electrode, and a second electrode. The control electrode is a gate electrode of the transistor, the first electrode is one of a source electrode and a drain electrode of the transistor, and the second electrode is the other of the source electrode and the drain electrode of the transistor. Since the source electrode and the drain electrode of the transistor may be symmetrical in structure, there may be no difference in structure between the source electrode and the drain electrode, and the source electrode of the transistor is referred to as the first electrode or the second electrode.

FIG. 1 is a schematic diagram illustrating a stacking relationship of a plurality of layers included in a display panel according to some embodiments of the present disclosure. As shown in FIG. 1, the display substrate 10 includes: a backplane layer (BP Layer) 100 and a light emitting device layer. The backplane layer 100 includes the above-described base substrate and a pixel driving circuit layer disposed on the base substrate. The pixel driving circuit layer includes a plurality of pixel driving circuits arranged in an array in the first direction and the second direction. The light emitting device layer is configured to form the light emitting device 101 of each sub-pixel. The light emitting device layer and the pixel driving circuit layer together form the plurality of pixel units arranged on the base substrate.

For example, the pixel driving circuit layer may include functional layers, including an active layer, a first gate metal layer (Gate1), a second gate metal layer (Gate2), a first metal wiring layer (SD1), and a second metal wiring layer (SD2), which are configured to form the transistors, the capacitor, and a plurality of signal lines for pixel driving of the pixel driving circuit. For example, the plurality of signal lines may include power signal lines, data signal lines, reset signal lines, scanning signal lines, enabling signal lines, initialization signal lines, and the like, of which detailed description may be refer to the related art, and is omitted herein. The pixel driving circuit layer may further include an insulating layer separating the functional layers. It should be noted that the functional layers of the pixel driving circuit layer listed above are only illustrative, and in other examples, the pixel driving circuit layer may also include more or less functional layers, for example, may also include more metal wiring layers, which may be set according to the requirements of an actual product, and is not limited in the present embodiment.

As shown in FIG. 1, the light emitting device layer may include a pixel defining layer 102 and a plurality of light emitting devices 101. The pixel defining layer 102 has a plurality of pixel openings, and each pixel opening defines a position of one of the light emitting devices 101. For example, a material of the pixel defining layer 102 may include a black light shielding material, so as to absorb the ambient light incident from the outside, thereby reducing a reflectivity of the ambient light of the display panel, and reducing a crosstalk between adjacent sub-pixels.

For example, each light emitting device 101 may include an anode, a light emitting layer, and a cathode, which are sequentially stacked together in a direction away from the base substrate. Alternatively, the light emitting device layer may further include at least one of a hole injection layer, a hole transport layer, and an electron blocking layer which are disposed between the anode and the light emitting layer, and at least one of an electron injection layer, an electron transport layer, and a hole blocking layer which are disposed between the cathode and the light emitting layer, which may be set according to practical requirements, and is not limited in the present embodiment.

For example, the anode may have a composite structure in which a transparent conductive oxide film/a metal film/a transparent conductive oxide film are sequentially stacked together. A material of the transparent conductive oxide film is, for example, any one of indium tin oxide (ITO) or indium zinc oxide (IZO), and a material of the metal film is, for example, any one of gold (Au), silver (Ag), nickel (Ni), or platinum (Pt). For example, the anode may have a single-layer structure, and the single-layer structure may be made of any one of ITO, IZO, Au, Ag, Ni, or Pt.

Each pixel opening exposes a partial region of the anode of a corresponding light emitting device 101, and at least a partial region of the light emitting layer is positioned within the corresponding pixel opening to form an electrical connection with the corresponding anode.

For example, the cathodes of the light emitting devices 101 may be electrically connected to each other to form a one-piece structure. For example, a material of the cathode may be any one of aluminum (Al), silver (Ag), or magnesium (Mg), or any one of a magnesium-silver alloy or an aluminum-lithium alloy.

In order to protect the light emitting devices 101, the display panel further includes an encapsulation layer disposed on a side of the light emitting device layer distal to the base substrate. The color filter layer 13 is arranged on a side of the encapsulation layer distal to the base substrate.

In some examples, the display panel may include a first inorganic encapsulation layer 111, an organic encapsulation layer 112, and a second inorganic encapsulation layer 113. As shown in FIG. 1, as an embodiment, the first inorganic encapsulation layer 111 is disposed on a side of the light emitting device layer proximal to the color filter layer 13 and the tactile sensor units 20, i.e., between the color filter layer 13 and the light emitting device layer, and the organic encapsulation layer 112 and the second inorganic encapsulation layer 113 may be sequentially stacked together on a side of the color filter layer 13 and the tactile sensor units 20 distal to the light emitting device layer. In this way, the color filter layer 13 and the tactile sensor units 20 are disposed in the encapsulation layer of the light emitting device layer, which is beneficial to, on one hand, reducing a distance between a color filter unit 131 and a corresponding light emitting device 101 in a direction perpendicular to the base substrate, so as to solve the problem of viewing angle brightness attenuation (which may be referred to as L_decay), and on the other hand, can also realize the encapsulation protection of the color filter unit 131 and the tactile sensor units 20.

Alternatively, in other examples, the first inorganic encapsulation layer 111, the organic encapsulation layer 112, and the second inorganic encapsulation layer 113 may be disposed between the color filter layer 13 and the light emitting device layer, which may be set according to practical requirements, and is not limited in the present embodiment.

The color filter layer 13 may include a plurality of color filter units 131. Each color filter unit 131 at least corresponds to one sub-pixel, for example, a red sub-pixel corresponds to a red color filter unit 131R, a green sub-pixel corresponds to a green color filter unit 131G, and a blue sub-pixel corresponds to a blue color filter unit 131B.

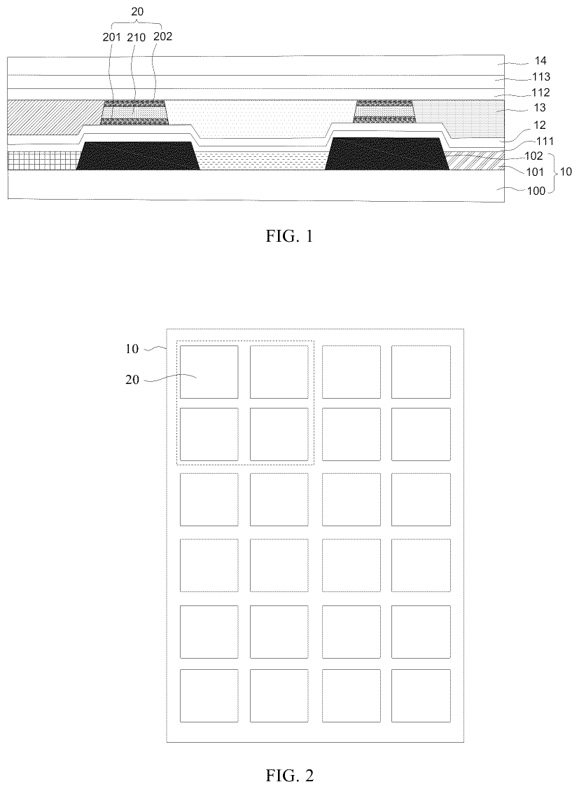

An opening region 132 is formed between any adjacent ones color filter units 131, and the plurality of tactile sensor units 20 are disposed in opening regions 132, respectively. The touch function of the display panel may be implemented by the plurality of tactile sensor units 20. For example, FIG. 2 illustrates an exemplary arrangement of the tactile sensor units 20, and each solid small box in FIG. 2 represents one tactile sensor unit 20. As shown in FIG. 2, the plurality of tactile sensor units 20 may be distributed in an array on the display substrate 10. It should be noted that the number, shapes and arrangement of the tactile sensor units 20 shown in FIG. 2 are only illustrative, but not restrictive, and may be set according to practical requirements. By storing position information of each of the tactile sensor units 20 on the screen in advance and processing a touch signal of each tactile sensor unit 20, a capacitance value change of each tactile sensor unit 20 can be detected, and thus whether touch operation occurs on the screen and a position where the touch operation occurs can be determined.

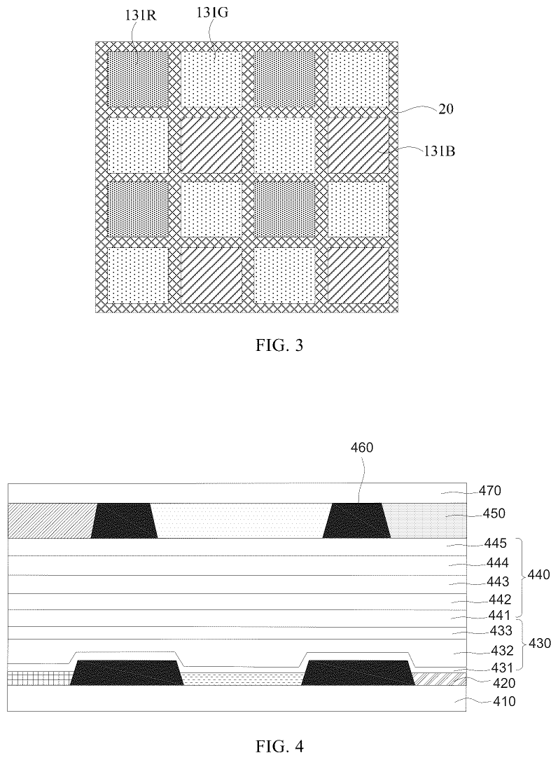

For example, each tactile sensor unit 20 may correspond to a×b sub-pixels, where each of a and b is an integer greater than or equal to 1, and may be set according to the requirements of an actual touch precision. FIG. 3 illustrates a schematic top view of a single tactile sensor unit 20 shown in FIG. 2, by taking an example that each tactile sensor unit 20 corresponds to 4×4 sub-pixels. As shown in FIG. 3, the tactile sensor unit 20 is disposed in the opening region 132 between the 4×4 color filter units 131 corresponding to the 4×4 sub-pixels, and has a grid-like structure.

Each tactile sensor unit 20 includes a black light shielding material, and an orthogonal projection of the black light shielding material on the base substrate covers a corresponding opening region 132 between the color filter units 131. For example, an orthogonal projection of an upper side of the opening region 132 between the color filter units 131 on the base substrate is located in an orthogonal projection of a distribution region of the black light shielding material on the base substrate. That is, the tactile sensor units 20 are configured to not only implement the touch function, but also replace the conventional black matrix as a light shielding structure to absorb the external ambient light, such that the display panel is in a dark state when turned off.

FIG. 4 is a schematic diagram illustrating a structure of a COE display panel according to a comparative embodiment. As shown in FIG. 4, the display panel includes, from bottom to top: a backplane layer 410, a light emitting device layer 420, an encapsulation layer 430, a touch structure layer 440, a color filter layer 450, a black matrix 460, and a cover plate 470. The encapsulation layer 430 includes a first inorganic encapsulation layer 431, an organic encapsulation layer 432, and a second inorganic encapsulation layer 433. The touch structure layer 440 includes a first inorganic insulating layer (e.g., silicon nitride) 441, a first touch metal layer 442, a second inorganic insulating layer (e.g., silicon nitride) 443, a second touch metal layer 444, and an organic layer 445, which are sequentially stacked together. In this configuration, the touch structure layer 440 is disposed between the encapsulation layer 430 and the color filter layer 450, such that a distance between the color filter layer 450 and each light emitting device in a direction perpendicular to a base substrate is relatively great, and in this case, the black matrix 460 will block the light emitted from the light emitting devices 101, thereby affecting a light emitting path at a side viewing angle, causing a greater viewing angle brightness attenuation (which may be referred to as L_decay), and affecting a user experience. Further, a reflectivity is great in a dark state, a process flow is complex, and so on.

Compared with the comparative embodiment, the display panel according to an embodiment of the present disclosure omits the conventional black matrix 460 between the touch structure layer 440 and the color filter units 131, and includes the plurality of tactile sensor units 20 respectively in the opening regions 132 between the color filter units 131, so as to implement the touch function and the light shielding function. As such, on one hand, the distance between the color filter layer 13 and each light emitting device 101 in the direction perpendicular to the base substrate can be reduced, such that the absorption of the light with a large viewing angle emitted from each light emitting device 101 by the black light shielding material contained in the tactile sensor units 20 is reduced, and the problem that the viewing angle brightness attenuation of the traditional touch product based on the COE technology is too fast is effectively solved. On the other hand, a thickness of the display panel can be reduced, for example, the thickness can be reduced by 1 μm to 5 μm. Thus, the display panel is easily to be folded and has a thinner screen, and a smaller stress will be generated at a folding position.

As shown in FIG. 1, in some examples, each of the tactile sensor units 20 may include a first electrode layer 201, a second electrode layer 202, and an electrolyte layer 210 located between the first electrode layer 201 and the second electrode layer 202. In a specific implementation, the first electrode layer 201 receives a first voltage signal, and the second electrode layer 202 receives a second voltage signal, the first voltage signal and the second voltage signal having a voltage difference therebetween, i.e., one of the first electrode layer 201 and the second electrode layer 202 being positively charged, and the other of the first electrode layer 201 and the second electrode layer 202 being negatively charged. The first voltage signal and the second voltage signal may be set according to a practical application scenario, for example, one of the first voltage signal and the second voltage signal may be a positive voltage signal, and the other of the first voltage signal and the second voltage signal may be a zero voltage signal or a negative voltage signal.

For convenience of wiring, in some examples, one of the first electrode layer 201 and the second electrode layer 202 may be grounded, and the other thereof may be connected to a signal input terminal of a capacitance detection circuit. Since a voltage of the signal input terminal is positive, the grounded electrode layer is charged negatively, and the electrode layer connected to the signal input terminal is charged positively.

An interface between the first electrode layer 201 and the electrolyte layer 210 is a first interface 221, and an interface between the second electrode layer 202 and the electrolyte layer 210 is a second interface 222. The electrolyte layer 210 includes positively charged ions and negatively charged ions. In a case where one of the first electrode layer 201 and the second electrode layer 202 is positively charged and the other thereof is negatively charged, under the action of Coulomb force, the positive charges and the negative charges in the electrolyte layer 210 are respectively attracted to the first interface 221 and the second interface 222, and interface capacitances, which form an electric double layer capacitor, are respectively formed at the first interface 221 and the second interface 222, such that a specific capacitance with an ultra-high capacitance value can be provided. The interface capacitances at the first interface 221 and/or the second interface 222 may be changed in response to a touch operation performed by a user, i.e., the total capacitance of the tactile sensor units 20 may also be changed, and may be recovered after the touch operation is finished. The capacitance detection circuit can detect a change in capacitance of the tactile sensor units 20 at a corresponding position, thereby implementing a touch function.

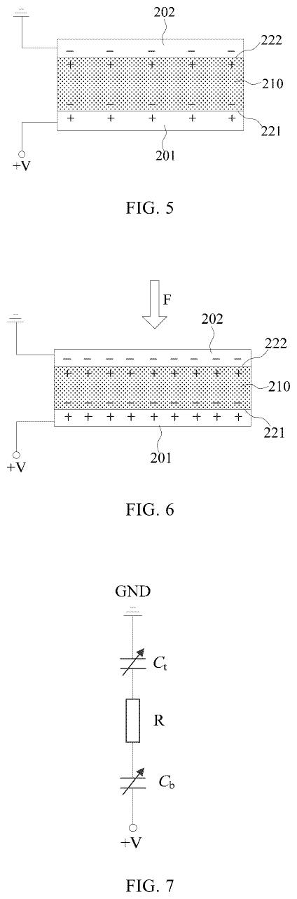

As shown in FIG. 5, for example, the second electrode layer 202 is grounded, and the first electrode layer 201 is connected to the capacitance detection circuit, such that the first electrode layer 201 is positively charged and the second electrode layer 202 is negatively charged. Negative charges in the electrolyte layer 210 are attracted to the first interface 221 by Coulomb force and arranged to form an interface capacitance, and positive charges are attracted to the second interface 222 by Coulomb force and arranged to form an interface capacitance, i.e., the electric double layer (EDL) capacitor is formed.

In some examples, at least one of the first electrode layer 201, the second electrode layer 202, or the electrolyte layer 210 has gaps (i.e., pores) therein. When a user performs a touch operation, the gaps at a corresponding position is compressed under the action of pressure in the direction perpendicular to the base substrate, an effective contact area of the first interface 221 and/or the second interface 222 is increased, and the interface capacitance is increased. After the touch operation is finished, the first electrode layer 201, the second electrode layer 202, and the electrolyte layer 210 are recovered from the compressed state, and the interface capacitance is recovered to the capacitance value before being compressed.

In an example where each of the first electrode layer 201, the second electrode layer 202, and the electrolyte layer 210 has gaps therein, the touch process and principle of the display panel may include two stages, which are a first stage and a second stage, the first stage being a stage during which the screen remains in the original state, and the second stage being a stage during which the screen is touched by a finger and a pressure on the screen is increased.

The first stage is as shown in FIG. 5, the screen is not subjected to an external force. A direct contact area (i.e. an effective contact area) between both the first electrode layer 201 and the second electrode layer 202 and the electrolyte layer 210 is small due to existence of the gaps, and such the loose contact causes a small amount of charge pairs to be arranged at the first interface 221 and the second interface 222 by Coulomb force attraction. In this case, the capacitance value is small. For convenience of distinction, the capacitance value of the tactile sensor units 20 during the first stage is referred to as an initial capacitance value.

The second stage is as shown in FIG. 6, the screen is touched by a finger and a pressure F on the screen is increased. The gaps in the first electrode layer 201, the second electrode layer 202, and the electrolyte layer 210 are compressed, a distance between the first electrode layer 201 and the second electrode layer 202 is decreased; the effective contact areas at the first interface 221 and the second interface 222 are increased, and an electric field is enhanced. As such, more charge pairs are forced to migrate to the first interface 221 and the second interface 222, so as to obtain a higher measurement capacitance. The electric double layer capacitor formed based on an ionization effect has a higher capacitance value, and is at least 3 orders of magnitude larger than that of a traditional parallel plate capacitive tactile sensor based on electrostatic charges, such that a touch detection precision is improved.

It should be noted that, after the second stage is finished, i.e. the finger leaves the screen, the tactile sensor units 20 recovers to have the initial capacitance value of the first stage as the compressed gaps recover.

FIG. 7 is a schematic diagram illustrating an equivalent circuit of each of the tactile sensor units 20. In FIG. 7, the interface capacitance formed at the first interface 221 in FIGS. 5 and 6 is represented as an equivalent capacitance Cb, the interface capacitance formed at the second interface 222 in FIGS. 5 and 6 is represented as an equivalent capacitance Ct, and a resistance of the electrolyte layer 210 is represented as an equivalent resistance R. As shown in FIG. 7, a first terminal of the equivalent capacitance Ct is grounded, a second terminal of the equivalent capacitance Ct, the equivalent resistance R, and a first terminal of the equivalent capacitance Cb are connected in series, and a second terminal of the equivalent capacitance Cb is connected to the capacitance detection circuit, for example, a voltage at the connection terminal may be represented as +V. When the capacitance value(s) of the capacitance Ct and/or the capacitance Cb are changed, the total capacitance value Ctotal of the tactile sensor unit 20 is also changed, thereby implementing touch detection.

In order to reduce the number of arranged film layers as much as possible and simplify the process thereof, at least one of the first electrode layer 201, the second electrode layer 202, or the electrolyte layer 210 may include the black light shielding material, when a material of each film layer is selected, and therefore, have a light shielding function, and an orthogonal projection of the black light shielding material on the base substrate covers a corresponding opening region 132 between the color filter units 131. For example, each of the first electrode layer 201 and the second electrode layer 202 may include the black light shielding material to achieve a better light shielding effect and reduce the reflectivity of the ambient light in a dark state.

In some examples, each of the first electrode layer 201 and the second electrode layer 202 may include a composite layer of polymer fiber and conductive nano material. In an optional embodiment, the conductive nano material may be randomly distributed on the polymer material fiber to form a conductive network structure. The polymer material fiber has a large gap ratio (i.e., a large porosity) and a good resilience, and is beneficial to increasing a capacitance variation when a user touches the screen and recovering when the touch is finished. For example, the polymeric material may include one or more of thermoplastic polyurethane (TPU), polypropylene (PP), polyvinylidene fluoride (PVDF), polyethylene, or nylon.

There are many kinds of conductive nano materials, and in an optional embodiment, in order to enable each of the first electrode layer 201 and the second electrode layer 202 to further have the light shielding function, the adopted conductive nano material may be a black conductive nano material, such as carbon fiber, carbon nanotube, grapheme, or the like. The black conductive nano material is distributed on the polymer material fiber, such that each of the first electrode layer 201 and the second electrode layer 202 has a black porous structure. As such, in a screen off state, on one hand, the black material can absorb ambient light, and on the other hand, the ambient light can be reflected for multiple times in the internal fiber structure, such that the ambient light is attenuated, and the reflectivity of the screen in the screen off state is reduced.

In some examples, the electrolyte layer 210 may include a composite fiber of polymer material and electrolyte material. For example, in order to increase a compressibility of the electrolyte layer 210 and further reduce the distance between the first electrode layer 201 and the second electrode layer 202 in the second stage, the polymer material in the electrolyte layer 210 may be an elastic polymer material, and for example, the elastic polymer material may include, but is not limited to, any one or more of thermoplastic polyurethane (TPU), polyethylene, or nylon. It should be noted that, the polymer material of the electrolyte layer 210 may be the same as or different from the polymer material of each of the first electrode layer and the second electrode layer 202, which is not limited in the present embodiment. For example, the electrolyte material includes one or more of: 1-hexyl-3-methylimidazolium tetrafluoroborate, 1-butyl-3-methylimidazolium tetrafluoroborate, or tert-butyl peroxyacetate (which may also be referred to as “tert-butyl ethaneperoxoate”).

For example, in some application scenarios, each of the first electrode layer 201 and the second electrode layer 202 may be a composite layer of the TPU fiber and the carbon fiber (or the carbon nanotube), and the electrolyte layer 210 may be a composite fiber layer of TPU and a solid electrolyte.

Compared with the touch structure layer 440 including multiple touch metal layers and multiple inorganic insulating layers according to the comparative embodiment shown in FIG. 4, each of the tactile sensor units 20 mainly includes organic materials, which is beneficial to improving a bending performance when being applied to a COE foldable product.

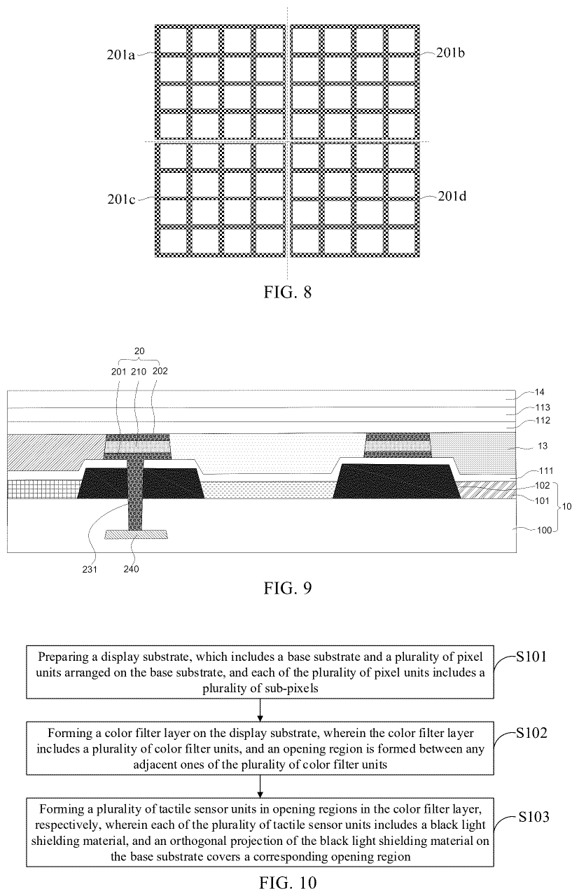

In order to detect the information of touch position, the touch signals of the plurality of tactile sensor units 20 need to be independently output to detect a change in the capacitance value of each tactile sensor unit 20. The first electrode layers 201 of any adjacent two tactile sensor units 20 are separated from each other, such that the first electrode layers 201 of different tactile sensor units 20 are insulated from each other and have a plurality of mutually independent grid-like structures. For example, if m×n tactile sensor units 20 are arranged in the display panel, m×n first electrode layers 201 having a grid-like structure need to be correspondingly arranged. FIG. 8 takes the 2×2 tactile sensor units 20 each surrounded by a dashed frame in FIG. 2 as an example, and illustrates a schematic layout of the first electrode layers 201 of the tactile sensor units 20. As shown in FIG. 8, the first electrode layers 201a, 201b, 201c, and 201d of the four tactile sensor units 20 are spaced apart and insulated from each other.

To simplify the process, in some examples, the second electrode layers 202 of the plurality of tactile sensor units 20 may be connected to each other to have a one-piece grid-like structure, the electrolyte layers 210 of the plurality of tactile sensor units 20 may also be connected to each other to have a one-piece grid-like structure.

Alternatively, other tactile sensors applicable to the display panel may be adopted as the tactile sensor units 20, instead of the electric double layer capacitor structure described above. For example, each of the tactile sensor units 20 may be a capacitive flexible tactile sensor, and in this case, includes an upper electrode, a lower electrode, and a flexible insulating medium sandwiched between the upper electrode and the lower electrode. When being subjected to press of an external force, the flexible insulating medium is compressed, a distance between the upper electrode and the lower electrode is reduced, and a capacitance is increased. After the external force is released, the flexible insulating medium can rebound to the initial position due to its elasticity, and the capacitance value of the capacitive flexible tactile sensor can also be restored to the initial value, such that a change in capacitance of the tactile sensor unit 20 at a corresponding position can be detected by the capacitance detection circuit, and the touch function can be realized. For another example, each tactile sensor unit 20 may also be a triboelectric type tactile sensor (which may also be referred to as “frictional electric tactile sensor”). An embodiment of the present disclosure is not limited thereto.

In some examples, the display panel further includes a grounding signal line and touch signal lines corresponding to the plurality of tactile sensor units 20, respectively. Each first electrode layer 201 is connected to a corresponding touch signal line, and each the touch signal line 240 is configured to transmit a touch signal of a corresponding tactile sensor unit 20. The second electrode layer 202 of each of the tactile sensor units 20 is connected to the grounding signal line. For example, the touch signal of each tactile sensor unit 20 may be led out to a border region of the display panel through a corresponding touch signal line, and then a line is wired from the border region to transmit the touch signal to the capacitance detection circuit. For example, the capacitance detection circuit may be disposed on a flexible printed circuit (FPC) and bound to the display panel.

There are various ways for disposing the touch signal lines 240, and two ways for disposing the touch signal lines will be described below by taking an example in which the first electrode layer 201 is closer to the display substrate 10 than the second electrode layer 202.

In a first way, each touch signal line 240 may be disposed on a side of the light emitting device layer distal to the base substrate. For example, the display panel further includes a conductive pattern layer 12 disposed on a side of each first electrode layer 201 proximal to the display substrate 10, and the touch signal lines are disposed in the conductive pattern layer 12. For example, as shown in FIG. 1, the first inorganic encapsulation layer 111 and the conductive pattern layer 12 are sequentially stacked on the side of the light emitting device layer distal to the base substrate, such that each touch signal line can be in contact connection with the first electrode layer 201 of a corresponding tactile sensor unit 20 without an additional process for forming a via.

For example, a material of the conductive pattern layer 12 may be a transparent conductive material such as ITO, to facilitate wiring and reduce an influence on a display brightness.

In a second way, as shown in FIG. 9, the touch signal lines 240 may be disposed in a metal wiring layer disposed between the base substrate and the light emitting device layer, i.e., the touch signal lines 240 may be disposed in the backplane layer 100. The first electrode layer 201 of each tactile sensor unit 20 is connected to the corresponding touch signal line 240 through a via. For example, the touch signal line 240 of each tactile sensor unit 20 may be provided in the first metal wiring layer (SD1) of the pixel driving circuit layer, or, a metal wiring layer for disposing the touch signal lines 240 may be additionally provided in the backplane layer 100, which may be set according to practical requirements, and is not limited in the present embodiment.

In an example in which the touch signal line 240 of each tactile sensor unit 20 is disposed in the first metal wiring layer (SD1), along the direction perpendicular to the base substrate, the insulating layer (such as the first inorganic encapsulation layer 111 shown in FIG. 9) between each first electrode layer 201 and the pixel defining layer 102, the pixel defining layer 102, and the insulating layer (such as a planarization layer) between the pixel defining layer 102 and the first metal wiring layer (SD1) may be provided therein with vias that are sequentially in communication with each other, a connection member 231 is provided in the vias, and the first electrode layer 201 of each tactile sensor unit 20 is connected to a corresponding touch signal line 240 in the first metal wiring layer (SD1) through the connection member 231. A material of the connection member 231 is a conductive material, and for example, may be the same as or different from the material of the first electrode layer 201.

In some embodiments, the display panel further includes a protective layer 14, and for example, a material of the protective layer 14 may include a cured film (e.g., an overcoat, OC), PET, ultra-thin glass (UTG), colorless polyimide (CPI), and/or the like, which is not limited in the present embodiment. For example, as shown in FIGS. 1 and 9, in a case where the organic encapsulation layer 112 and the second inorganic encapsulation layer 113 are sequentially stacked on a side of the color filter layer 13 distal to the base substrate, the protective layer 14 may be disposed on a side of the second inorganic encapsulation layer 113 distal to the base substrate.

In a second aspect, some embodiments of the present disclosure further provide a method for manufacturing a display panel, and the method may be adopted to manufacture the display panel according to any one of the embodiments in the first aspect. As shown in FIG. 10, the method may include the following steps S101 to S103.

Step S101 includes preparing the display substrate, which includes the base substrate and the plurality of pixel units arranged on the base substrate, and each of the plurality of pixel units includes a plurality of sub-pixels.

Step S102 includes forming a color filter layer on the display substrate, wherein the color filter layer includes a plurality of color filter units, and an opening region is formed between any adjacent ones of the plurality of color filter units.

Step S103 includes forming a plurality of tactile sensor units in respective opening regions in the color filter layer, wherein each of the plurality of tactile sensor units includes a black light shielding material, and an orthogonal projection of the black light shielding material on the base substrate covers a corresponding opening region.

In some examples, the step of forming the plurality of tactile sensor units 20 in the respective opening regions 132 in the color filter layer 13 may include: forming the first electrode layers 201 of the tactile sensor units 20 in the respective opening regions 132 in the color filter layer 13, wherein the first electrode layers 201 of any adjacent two of the tactile sensor units 20 are spaced apart from each other; forming the electrolyte layers 210 on the first electrode layers 201 in the respective opening regions 132; and forming the second electrode layers 202 on the electrolyte layers 210 in the respective opening regions 132.

For ease of understanding, two exemplary manufacturing processes for the display panel will be described below.

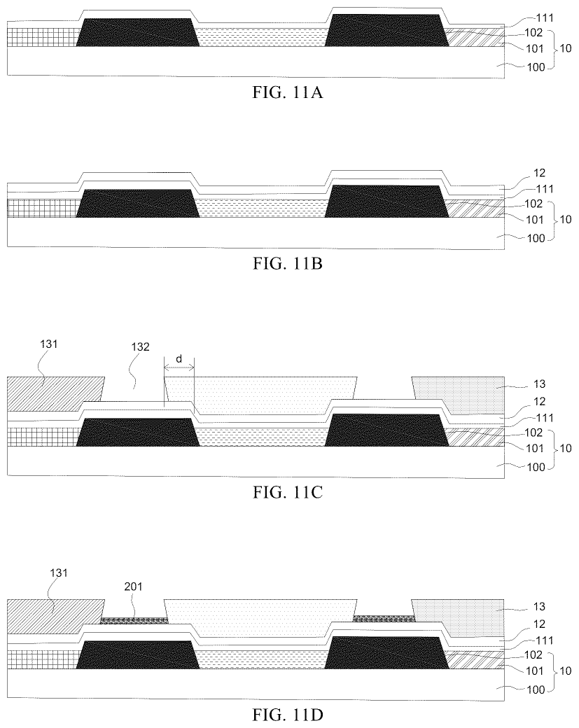

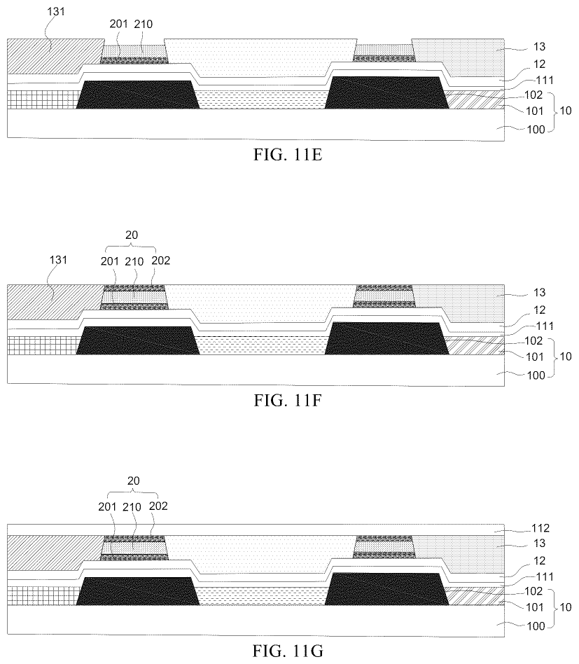

Referring to FIGS. 11A to 11H, a first exemplary manufacturing process may include the following steps (1) to (10).

Step (1) includes forming a light emitting device layer on the backplane layer 100, to obtain the display substrate 10 including the plurality of pixel units.

Step (2) includes forming the first inorganic encapsulation layer 111 on the light emitting device layer by a chemical vapor deposition process (CVD1), as shown in FIG. 11A. For example, a material of the first inorganic encapsulation layer 111 may include any one or more of inorganic insulating materials such as nitride, oxide, oxynitride, nitrate, or the like. For example, a thickness of the first inorganic encapsulation layer 111 may be 1 μm to 3 μm, such as 2 μm.

Step (3) includes forming the conductive pattern layer 12 on the first inorganic encapsulation layer 111 (CVD1) according to a pre-designed layout of the touch signal line 240 of each tactile sensor unit 20, as shown in FIG. 11B, wherein the conductive pattern layer 12 includes touch signal lines corresponding to the respective tactile sensor units 20. For example, the conductive pattern layer 12 may be made of a transparent conductive material such as ITO, and have a trace width of 2 μm to 4 μm, such as 2 μm.

Sep (4) includes forming the color filter layer 13 on the conductive pattern layer 12, as shown in FIG. 11C. For example, the color filter layer 13 may include a red color filter unit 131 (R CF), a green color filter unit 131 (G CF), and a blue color filter unit 131 (B CF), wherein each color filter unit 131 corresponds to one of the light emitting devices 101. An opening region 132 is formed between any adjacent two of the color filter units 131. For example, a thickness of each color filter unit 131 may be 2 μm to 7 μm, and a horizontal distance d between a boundary of a color filter unit 131 and a boundary, which is located on the same side as the boundary of the color filter unit 131, of the light emitting device 101, which is under the color filter unit 131, is 2 μm to 7 μm. For example, in a case where the thickness of each of the red color filter unit 131, the green color filter unit 131, and the blue color filter unit 131 is 5 μm, the horizontal distance d between the boundary of the color filter unit 131 and the boundary, which is located on the same side as the boundary of the color filter unit 131, of the light emitting device 101, which is under the color filter unit 131, may be 4 μm. In a case where the red color filter unit 131, the green color filter unit 131, and the blue color filter unit 131 have the thicknesses of 3 μm, 3 μm, and 4 μm, respectively, the horizontal distance d between the boundary of the color filter unit 131 and the boundary, which is located on the same side as the boundary of the color filter unit 131, of the light emitting device 101, which is under the color filter unit 131, may be 3 μm.

Step (5) includes dissolving the conductive nano material and the polymer material by using a chemical solvent and blending them into a uniform mixture by means of ultrasonic oscillation, and forming a fiber composite film of the conductive nano material/polymer in the opening regions 132 of the color filter layer 13 by means of electrostatic spinning, so as to obtain the first electrode layers 201 of the tactile sensor units 20, as shown in FIG. 11D. The first electrode layer 201 of each tactile sensor unit 20 contacts at least a partial portion of a corresponding touch signal line in the conductive pattern layer 12, to realize connection between the first electrode layer 201 and the corresponding touch signal line 240.

The chemical solvent may include, but is not limited to, one or a combination of dimethylformamide, tetrahydrofuran, or the like. The conductive nano material is randomly distributed on the polymer fiber, has a high length-diameter ratio and a good conductivity, and forms a conductive network structure on the polymer fiber film.

A thickness of the composite layer of the polymer fiber and the conductive nano material may be 0.5 μm to 2 μm, such as 1 μm. A material of the polymer fiber may be one or more of polypropylene (PP), polyvinylidene fluoride (PVDF), thermoplastic polyurethane (TPU), polyethylene, or nylon. In order to make each first electrode layer 201 appear black, the conductive nano material may be a black conductive nano material such as carbon fiber, carbon nanotube, graphene, or the like.

Step (6) includes dissolving an ionic solution and the elastic polymer material by using a chemical solvent, blending them into a uniform mixture by means of ultrasonic oscillation, and forming a composite fiber layer of the polymer material and a solid electrolyte, i.e. forming the electrolyte layer 210, on the composite layer of the polymer fiber and the conductive nano material formed in step (5) by means of electrostatic spinning, as shown in FIG. 11E. For example, a thickness of the composite fiber layer may be 2 μm to 5 μm, and may be set to 5 μm.

For example, the ionic solution may be one or more of 1-hexyl-3-methylimidazolium tetrafluoroborate, 1-butyl-3-methylimidazolium tetrafluoroborate, or tert-butyl peroxyacetate. A type of the chemical solvent may be the same as that in step (5). The elastic polymer material may be one or more of thermoplastic polyurethane (TPU), polyethylene, or nylon.

Step (7) includes forming the second electrode layer 202 of each tactile sensor unit 20 on the electrolyte layer 210 formed in step (6), by means of electrostatic spinning, as shown in FIG. 11F. The preparation method and requirements thereof may be the same as those in step (5).

Step (8) includes forming the organic encapsulation layer 112 on the color filter layer 13 and the second electrode layers 202 of the tactile sensor units 20, as shown in FIG. 11G. For example, a layer of organic material may be formed on the color filter layer 13 and the second electrode layers 202 of the tactile sensor units 20 through an ink jet printing (IJP) process, to organically package the color filter layer 13 and the second electrode layers 202. For example, a thickness of the organic encapsulation layer 112 may be 6 μm to 12 μm, and for example, may be set to 8 μm.

Step (9) includes forming the second inorganic encapsulation layer 113 on the organic encapsulation layer 112 formed in step (8) by a chemical vapor deposition process (CVD2), as shown in FIG. 11H. For example, a thickness of the second inorganic encapsulation layer 113 (CVD 2) may be 0.5 μm to 3 μm, such as 0.8 μm. A material of the second inorganic encapsulation layer 113 (CVD2) may be silicon nitride.

Step (10) includes forming the protective layer 14 (e.g., a cover layer) on the second inorganic encapsulation layer 113 (CVD2) formed in the step shown in FIG. 11H, to obtain the display panel shown in FIG. 1. For example, a material of the protective layer 14 may include a cured film (OC), PET, ultra-thin glass (UTG), colorless polyimide (CPI), and/or the like.

It should be noted that, in the conventional touch process, the touch structure layer 440 according to the comparative embodiment as shown in FIG. 4 needs 5 masking processes, and each of the 5 masking processes needs at least 20 processes of coating, exposing, developing, and etching. Whereas in the above exemplary manufacturing process, the preparation of the touch layer only needs 4 processes of forming the conductive pattern layer 12, forming each first electrode layer 201 by means of electrostatic spinning, forming the electrolyte layer 210 by means of electrostatic spinning, and forming the second electrode layer 202 by means of electrostatic spinning, and a black matrix formation process (including 4 processes) is omitted, such that the number of processes can be reduced by 13 compared with the conventional COE product. Therefore, the display panel provided by some embodiments of the present disclosure is also beneficial to reducing the product manufacturing procedures, reducing the production time consumption, and reducing the production cost.

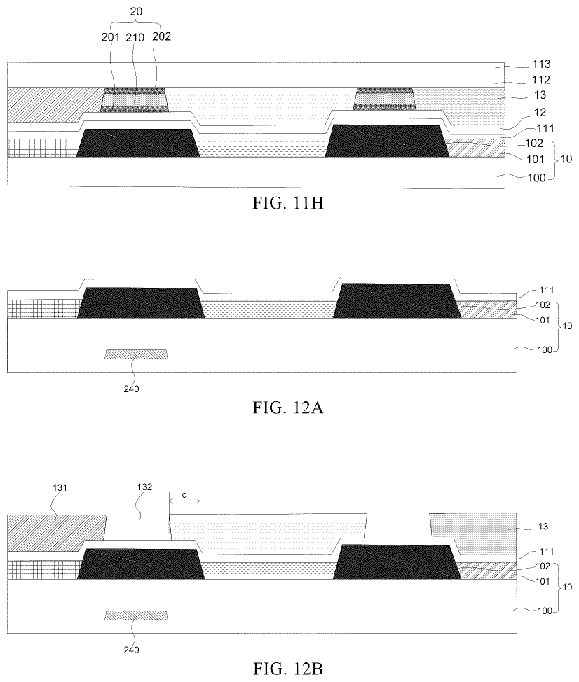

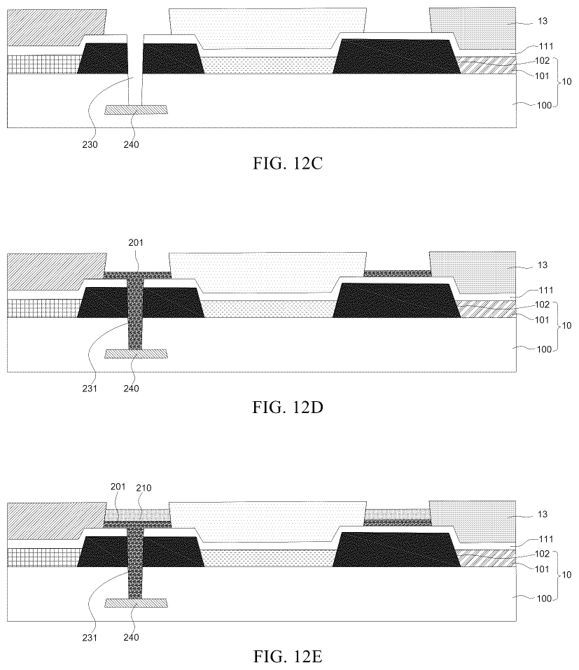

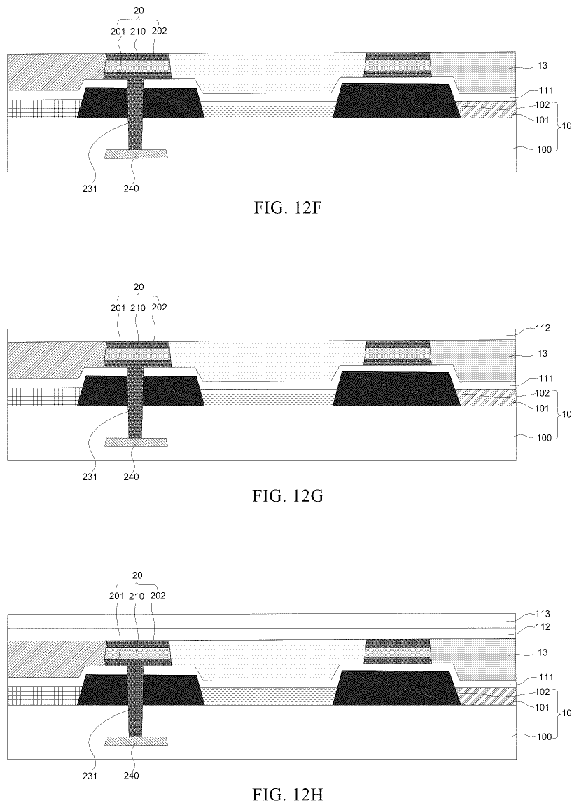

Referring to FIGS. 12A to 12H, a second exemplary manufacturing process may include the following steps (I) to (X).

Step (I) includes preparing the backplane layer 100, and forming the light emitting device layer on the backplane layer 100, to obtain the display substrate 10 including the plurality of pixel units. The backplane layer 100 includes the first metal wiring layer (SD1) and the second wiring layer (SD2), and a plurality of touch signal lines 240 are formed in the first metal wiring layer (SD1) according to a pre-designed layout of the touch signal lines 240 of the tactile sensor units 20, wherein each of the touch signal lines 240 corresponds to one of the tactile sensor units 20.

Step (II) includes forming the first inorganic encapsulation layer 111 on the light emitting device layer (CVD1), as shown in FIG. 12A, detailed description thereof may be referred to step (2) of the first exemplary manufacturing process, and is not repeated here.

Step (III) includes forming the color filter layer 13 on the first inorganic encapsulation layer 111 (CVD1), as shown in FIG. 12B, detailed description thereof may be referred to step (4) in the first exemplary manufacturing process, and is omitted here.

Step (IV) includes forming a hole 230 in a bottom of each opening region 132 in the color filter layer 13 is by laser drilling, as shown in FIG. 12C, and a position of the hole 230 starts from the first inorganic encapsulation layer 111 (CVD1) and ends at the first metal wiring layer (SD1). For example, a diameter of the hole may be 3 μm.

Step (V) includes forming the first electrode layer 201 of each tactile sensor unit 20 in a corresponding opening region 132 of the color filter layer 13, as shown in FIG. 12D. It should be noted that, in the process of forming the first electrode layer 201, the material of the first electrode layer 201 is filled into the hole 230 formed in step (IV), so as to realize the via connection between the first electrode layer 201 of the tactile sensor unit 20 and the corresponding touch signal line 240. The preparation process of the first electrode layer 201 may be referred to step (5) in the first exemplary manufacturing process, and is not repeated here.

Step (VI) includes forming the electrolyte layer 210 of each tactile sensor unit 20 on the first electrode layer 201 formed in step (V), as shown in FIG. 12E. The preparation process for the electrolyte layer 210 may be referred to step (6) in the first exemplary manufacturing process, and is not repeated here.

Step (VII) includes forming the second electrode layer 202 of each tactile sensor unit 20 on the electrolyte layer 210 formed in step (VI), as shown in FIG. 12F, detailed description thereof may be referred to step (7) in the first exemplary manufacturing process, and is not repeated here.

Step (VIII) includes forming the organic encapsulation layer 112 on the color filter layer 13 and the second electrode layers 202 of the tactile sensor units 20, as shown in FIG. 12G, detailed description thereof may be referred to step (8) in the first exemplary manufacturing process, and is not repeated here.

Step (IX) includes forming the second inorganic encapsulation layer 113 on the organic encapsulation layer 112 (CVD2), as shown in FIG. 12H, detailed description thereof may be referred to step (9) in the first exemplary manufacturing process, and is not repeated here.

Step (X) includes forming the protective layer 14 on the second inorganic encapsulation layer 113 (CVD2), to obtain the display panel shown in FIG. 9, detailed description thereof may be referred to step (10) in the first exemplary manufacturing process, and is not repeated here.

In a third aspect, some embodiments of the present disclosure further provide a touch display device, which includes the display panel according to any one of the foregoing embodiments of the present disclosure. For example, the touch display device may be a mobile phone, a tablet computer, a display, a vehicle-mounted display screen, a digital photo frame, an intelligent terminal, a smart television, a wearable display device, or the like, which is not limited in the present embodiment.

The technical solutions according to some embodiments of the present disclosure have at least the following technical effects or advantages. The display panel, the method for manufacturing the display panel, and the touch display device provided by some embodiments of the present disclosure omit a traditional touch structure layer and a black matrix, and realize the touch function by arranging the plurality of tactile sensor units in the respective opening regions between the color filter units. Further, each of the tactile sensor unit includes the black light shielding material, and the orthogonal projection of the black light shielding material on the base substrate covers the corresponding opening region, such that each of the tactile sensor units further has a light shielding function. As such, the distance between the color filter layer and each of the light emitting devices in the direction perpendicular to the base substrate can be reduced, and the absorption rate of light with a large viewing angle emitted from the light emitting devices, which is absorbed by each tactile sensor unit having the light shielding function, is reduced, such that the problem that the viewing angle brightness of the traditional touch product based on the COE technology is attenuated too fast is effectively solved.

In the foregoing description, details of the techniques such as patterning of the layers of a product may not be described in detail. It will be appreciated by one of ordinary skill in the art that layers, regions, and/or the like of a desired shape may be formed by various technical means. In addition, in order to form a same structure, one of ordinary skill in the art can also design a method which is not exactly the same as any one of the methods described above. Although the embodiments are described separately above, this does not mean that the measures in the embodiments cannot be used advantageously in combination.

Additionally, one of ordinary skill in the art will understand that the discussion of any one of the foregoing embodiments is merely exemplary and is not intended to limit the scope of the present disclosure to these examples. The foregoing embodiments, or features from different embodiments may be combined with each other. The steps may be implemented in any order, and there are many other variations of different aspects of one or more embodiments of the present disclosure, which are not provided in detail for the sake of brevity.

Although the exemplary embodiments of the present disclosure have been described, additional variations and modifications in these embodiments may be possible to one of ordinary skill in the art once he/she learns of the basic inventive concepts of the present disclosure. Therefore, it is intended that the appended claims are interpreted as including the exemplary embodiment and all variations and modifications that fall within the scope of the present disclosure.

1. A display panel, comprising:
a display substrate comprising a base substrate and a plurality of pixel units arranged on the base substrate, wherein each of the plurality of pixel units comprises a plurality of sub-pixels;
a color filter layer arranged on the display substrate and comprising a plurality of color filter units, wherein every adjacent ones of the plurality of color filter units have therebetween opening regions, respectively; and
a plurality of tactile sensor units disposed in the opening regions, respectively, wherein each of the plurality of tactile sensor units comprises a black light shielding material, and an orthogonal projection of the black light shielding material on the base substrate covers a respective opening region.

2. The display panel according to claim 1, wherein each of the tactile sensor units comprises a first electrode layer, a second electrode layer, and an electrolyte layer positioned between the first electrode layer and the second electrode layer, and at least one of the first electrode layer, the second electrode layer, or the electrolyte layer comprises the black light shielding material; and
an interface between the first electrode layer and the electrolyte layer is a first interface, an interface between the second electrode layer and the electrolyte layer is a second interface, the first electrode layer is configured to receive a first voltage signal, the second electrode layer is configured to receive a second voltage signal, the first voltage signal and the second voltage signal have therebetween a voltage difference such that interface capacitances are respectively formed at the first interface and the second interface, and the interface capacitances at the first interface and/or the second interface are changed in response to a touch operation performed by a user and are recovered after the touch operation is finished.

3. The display panel according to claim 2, wherein at least one of the first electrode layer, the second electrode layer, or the electrolyte layer has therein gaps, and in response to the touch operation performed by the user, the gaps at a corresponding position are compressed, such that an effective contact area at the first interface and/or the second interface is increased, and the interface capacitances are increased.

4. The display panel according to claim 2, wherein each of the first electrode layer and the second electrode layer comprises a composite layer of polymer fiber and conductive nano material, and the conductive nano material is a black conductive nano material; and
the electrolyte layer comprises a composite fiber of elastic polymer material and electrolyte material.

5. The display panel according to claim 4, wherein a material of the polymer fiber comprises one or more of thermoplastic polyurethane, polypropylene, polyvinylidene fluoride, polyethylene, or nylon;
the conductive nano material is carbon fiber, a carbon nanotube, or graphene;
the elastic polymer material comprises one or more of thermoplastic polyurethane, polyethylene, or nylon; and
the electrolyte material comprises one or more of 1-hexyl-3-methylimidazolium tetrafluoroborate, 1-butyl-3-methylimidazolium tetrafluoroborate, or tert-butyl peroxyacetate.

6. The display panel according to claim 2, wherein the first electrode layers of any adjacent two of the plurality of tactile sensor units are spaced apart from each other, and the second electrode layers of the plurality of tactile sensor units are connected to each other.

7. The display panel according to claim 2, further comprising a grounding signal line and touch signal lines corresponding to the respective tactile sensor units, wherein the first electrode layer of each tactile sensor unit is connected to a respective touch signal line, the touch signal lines are configured to transmit touch signals of the respective tactile sensor units, and the second electrode layers of the tactile sensor units are connected to the grounding signal line.

8. The display panel according to claim 7, wherein each first electrode layer is closer to the display substrate than a respective second electrode layer, the display panel further comprises a conductive pattern layer arranged on a side of each first electrode layer proximal to the display substrate, and the touch signal lines are arranged in the conductive pattern layer.

9. The display panel according to claim 8, wherein a material of the conductive pattern layer is a transparent conductive material.

10. The display panel according to claim 7, wherein each first electrode layer is closer to the display substrate than each second electrode layer, the display substrate comprises a light emitting device layer disposed on the base substrate, and the light emitting device layer comprises a plurality of light emitting devices for forming the plurality of pixel units; and
a metal wiring layer is arranged between the base substrate and the light emitting device layer, the touch signal lines are arranged in the metal wiring layer, and the first electrode layer of each tactile sensor unit is connected to a respective touch signal line through a via.

11. The display panel according to claim 10, wherein the light emitting device layer comprises a pixel defining layer having pixel openings within which the plurality of light emitting devices are respectively disposed; and
in a direction perpendicular to the base substrate, vias that are in communication with each other in sequence are formed in an insulating layer between each first electrode layer and the pixel defining layer, the pixel defining layer, and an insulating layer between the pixel defining layer and the metal wiring layer, a connection member is arranged in the vias, and the first electrode layer of each tactile sensor unit is connected to a respective touch signal line in the metal wiring layer through the connection member.

12. The display panel according to claim 1, further comprising a first inorganic encapsulation layer, an organic encapsulation layer, and a second inorganic encapsulation layer;
wherein the display substrate comprises a light emitting device layer arranged on the base substrate, the first inorganic encapsulation layer is arranged on a side of the light emitting device layer proximal to the color filter layer and the tactile sensor units, and the organic encapsulation layer and the second inorganic encapsulation layer are sequentially stacked on a side of the color filter layer and the tactile sensor units distal to the light emitting device layer.

13. A method for manufacturing a display panel, the method comprising:
preparing a display substrate, wherein the display substrate comprises a base substrate and a plurality of pixel units arranged on the base substrate, and each of plurality of pixel units comprises a plurality of sub-pixels;
forming a color filter layer on the display substrate, wherein the color filter layer comprises a plurality of color filter units, and every adjacent ones of the plurality of color filter units have therebetween opening regions, respectively; and
forming a plurality of tactile sensor units in the opening regions in the color filter layer, respectively, wherein each of the plurality of tactile sensor units comprises a black light shielding material, and an orthogonal projection of the black light shielding material on the base substrate covers a respective opening region.

14. The method according to claim 13, wherein the forming a plurality of tactile sensor units in the opening regions in the color filter layer comprises:
forming first electrode layers of the tactile sensor units in the respective opening regions, wherein the first electrode layers of any adjacent two of the tactile sensor units are spaced apart from each other;
forming an electrolyte layer on the first electrode layer in a respective opening region; and
forming a second electrode layer on the electrolyte layer in the respective opening region.

15. A touch display device, comprising the display panel according to claim 1.
